(19) United States
(12) Patent Application Publication
(10) Pub. No.: US 2026/0215307 A1
(43) Pub. Date: Jul. 23, 2026

(54) POWER SEMICONDUCTOR MODULE

(71) Applicants: Dynex Semiconductor Limited, Lincoln (GB); Zhuzhou CRRC Times Semiconductor Co. Ltd, Zhuzhou, Hunan (CN)

(72) Inventors: Robin Adam SIMPSON, Lincoln (GB); Michael David NICHOLSON, Lincoln (GB)

(21) Appl. No.: 19/141,747

(22) PCT Filed: Dec. 22, 2022
(86) PCT No.: PCT/EP2022/087490

§ 371 Date: Jun. 20, 2025

(51) Int. Cl. H10W 70/685; H10W 70/65; H10W 90/00

(52) U.S. Cl. CPC H10W 70/685; H10W 70/658; H10W 90/401; H10W 90/794

(57) ABSTRACT

A power semiconductor includes a substrate comprising an electrically insulating body and a patterned electrically conductive layer arranged on a surface of the electrically insulating body, wherein the patterned electrically conductive layer comprises first, second and third conductive tracks which are spaced apart from one another; a first power semiconductor device T1 and/or T2 comprising first and second power electrodes; a second power semiconductor device T3 and/or T4 comprising third and fourth power electrodes; and a circuit board comprising a plurality of electrically conductive layers stacked with a plurality of electrically insulating layers along a stacking direction Z; and the plurality of electrically conductive layers comprises first, second and third electrically conductive layers which are spaced apart from one another along the stacking direction.

### TECHNICAL FIELD

This disclosure relates to a power semiconductor module and a method of manufacturing the same. More particularly, but not exclusively, this disclosure relates to a single-side cooled power semiconductor module which uses a multi-layer circuit board to realise interconnections between power semiconductor devices and a substrate of the module.

### BACKGROUND

Wide bandgap (WBG) power semiconductor devices such as Gallium-Nitride High-electron-mobility transistors (GaN HEMTs) are capable of switching with faster slew rates than traditional silicon-based power semiconductor devices, such as metal-oxide-semiconductor field-effect transistors (MOSFETs). Energy loss during a switching transition is directly related to the time duration of the transition. Therefore, the ability to switch with faster slew rates leads to a reduction in switching energy loss and is a key advantage of power semiconductor devices made from WBG materials rather than silicon.

Traditional power modules, used for packaging silicon-based power semiconductor devices, are manufactured using patterned copper-clad ceramic substrates with wire-bonded interconnections between the copper tracks on the substrate and the chips. This technology is mature, flexible and suitable for mass production but brings with it a number of issues. First, the wire bonds have high inductances due to their relatively small cross-sectional area and sub-optimal shape. Second, the two-dimensional nature of the patterned copper on the substrate limits the capability of the designer to minimise inductances by forcing the use of indirect paths. Third, magnetic flux cancellation techniques, such as closely coupling conductors with opposing current flow directions, are difficult to achieve due to the looping shape of the bond wires. It is almost impossible to closely couple bond wires with opposing current flow directions.

High inductances are incompatible with switching at the faster slew rates enabled by WBG semiconductor devices. During turn-off of the device, a voltage overshoot above a DC supply voltage is generated across the module. The magnitude of the voltage overshoot is determined by the product of the current slew rate (dl/dt) and the stray inductance of the module. The voltage overshoot has two effects: (1) it increases switching losses by increasing the V*I product during the switching transition, (2) in extreme cases, it may lead to destruction of the power semiconductor device by exceeding its breakdown voltage.

Since wire bonds have high inductances, wire-bonded power module designs limit the maximum performance of WBG-based power semiconductor modules. To extract the ultimate performance of WBG semiconductor devices, packaging designs with reduced inductances are required.

High switching speeds also interact with parasitic capacitances and inductances to cause electromagnetic interference (EMI). High dV/dt transients interact with parasitic capacitances to produce displacement currents. High dl/dt transients interact with parasitic inductances to produce fluctuations in voltages. Current loops can cause radiated EMI. To minimise EMI, physical current loop sizes should be as small as possible, parasitic inductances should be minimised and balanced in the case of a configuration with both DC+ and DC− buses.

FIG. 1 schematically illustrates a half-bridge circuit structure 1000 with parasitic capacitances. The half-bridge structure includes a high-side power switch 1100 and a low-side power switch 1200 connected in series between a DC+ terminal and a DC− terminal. An output AC terminal is connected to a switching node between the high-side power switch and the low-side power switch. In use, the DC+, DC− and AC terminals are typically connected to conductive regions formed on an upper copper layer of a patterned copper-clad ceramic substrate. A lower copper layer of the substrate, separated from the upper copper layer by a ceramic layer, is typically connected to a ground terminal GND. Preferably, to minimise EMI, the parasitic capacitance C_{AC} between regions of the AC potential and GND should be minimised, while parasitic capacitance between DC+ and DC− (not shown in FIG. 1) should be maximised, with DC+ to ground and DC− to ground parasitic capacitances C_{DC+}, C_{DC-} being maximised and balanced. Traditional module designs using wire bonds have high inductances in the interconnections and lack the flexibility to enable these EMI mitigation steps.

It is an object of the present disclosure, among others, to provide an improved power semiconductor module that solves problems associated with conventional power semiconductor modules, whether identified herein or otherwise.

### SUMMARY

According to a first aspect of this disclosure there is provided a power semiconductor module comprising: a substrate comprising an electrically insulating body and a patterned electrically conductive layer arranged on a surface of the electrically insulating body, wherein the patterned electrically conductive layer comprises first, second and third conductive tracks which are spaced apart from one another; a first power semiconductor device comprising first and second power electrodes; a second power semiconductor device comprising third and fourth power electrodes; and a circuit board, wherein: the first and second power semiconductor devices are arranged between the circuit board and the substrate; the circuit board comprises a plurality of electrically conductive layers stacked with a plurality of electrically insulating layers along a stacking direction; at least one of the electrically insulating layers is arranged between adjacent ones of the electrically conductive layers; and the plurality of electrically conductive layers comprises first, second and third electrically conductive layers which are spaced apart from one another along the stacking direction; wherein: the first power electrode is electrically connected to the first electrically conductive layer, and the first electrically conductive layer is further electrically connected to the first conductive track; the second and third power electrodes are both electrically connected to the third electrically conductive layer, and the third electrically conductive layer is further electrically connected to the third conductive track; the fourth power electrode is electrically connected to the second electrically conductive layer, and the second electrically conductive layer is further electrically connected to the second conductive track; and the second electrically conductive layer is arranged between the first and third electrically conductive layers.

Within the present disclosure, the term “electrically connected” describes a permanent low-ohmic connection between electrically connected elements, for example a direct contact between the concerned elements or a low-ohmic connection via metal conductor(s).

Advantageously, the multi-layer circuit board is used to make the electrical interconnections between the first and second power semiconductor devices and the substrate (thereby realising a half-bridge circuit structure or the like). Power current loops of the circuit structure are contained primarily or solely within the electrically conductive layers of the circuit board. Thus, physical sizes of the power current loops are significantly reduced as compared to conventional power modules that use wire-bonded interconnections. Further, the distances between adjacent electrically conductive layers along the stacking direction are very short (e.g., a thickness of a single electrically insulating layer, in the order of tens of micrometres). Thus, electrically conductive layers with opposing current flow directions can be closely coupled to cancel magnetic flux generated by the current flows, thereby reducing parasitic inductances of the electrical interconnections between the power electrodes and the substrate. By reducing the physical sizes of the power current loops and reducing the parasitic inductances of the electrical interconnections, radiated EMI caused by operation of the module is significantly reduced. Reducing the parasitic inductances of the electrical interconnections is also useful for reducing voltage fluctuations in the power semiconductor module, and for reducing the magnitude of voltage overshoot above a DC supply voltage of the power semiconductor module.

With the electrical connections defined in the first aspect, it would be understood that the third electrically conductive layer may be electrically connected to a switching AC node of a half-bridge circuit structure, and that the first and second electrically conductive layers may be electrically connected to a DC positive node and a DC negative node of the half-bridge circuit structure (or vice versa). By arranging the second electrically conductive layer to be between the first and third electrically conductive layers, the first conductive layer (which may be connected to a more sensitive DC node depending upon system requirements) is shielded from electromagnetic emissions from the third electrically conductive layer. This is beneficial for reducing noises on the first conductive layer (hence the sensitive DC node), thereby improving the performance of the power semiconductor module or an upper-level power electronics system which uses the power semiconductor module.

In addition, by arranging the second electrically conductive layer to be between the first and third electrically conductive layers, the first and second electrically conductive layers can be arranged in close proximity. This arrangement is useful for maximising the parasitic capacitance between the first and second electrically conductive layers (e.g., the parasitic capacitance between the DC positive node and the DC negative node of the half-bridge circuit structure), and thus useful for reducing line voltage ripples caused by high speed current transients produced by operation of the module.

It would be understood that the first/second power semiconductor device may comprise more than one power semiconductor die which are electrically connected together in any suitable manner (e.g., in series or in parallel).

The surface of the electrically insulating body may define a lateral direction. The first and second power semiconductor devices may be arranged along the lateral direction.

The power semiconductor module may be a single-side cooled module. In other words, the power semiconductor module may comprise a single substrate.

The circuit board, the first and second power semiconductor devices, and the patterned electrically conductive layer may be arranged at the same side of the electrically insulating body.

It would be understood that the electrically insulating body is thermally conductive.

The stacking direction may be generally perpendicular to the surface of the electrically insulating body.

The third electrically conductive layer may be further away from the substrate than the first electrically conductive layer along the stacking direction.

Advantageously, by arranging the third electrically conductive layer away from the substrate, the parasitic capacitance between the third electrically conductive layer (which may be connected to the switching AC node of a half-bridge circuit structure) and ground (which may be connected to a bottom layer of the substrate) can be reduced, thereby improving the switching speed of the power semiconductor module.

The first and second electrically conductive layers may be separated by a single electrically insulating layer.

The first and second conductive tracks may occupy approximately the same area on the electrically insulating body.

Advantageously, this arrangement is useful for balancing parasitic capacitances from the DC positive node to ground and from the DC negative node to ground. Balanced capacitances to ground minimise differential currents that are a cause of EMI.

The first power semiconductor device may be configured to block a voltage with a higher potential at the second power electrode than at the first power electrode.

The second power semiconductor device may be configured to block a voltage with a higher potential at the fourth power electrode than at the third power electrode. One or more of the first and second power semiconductor devices may be a uni-directional power semiconductor device. The term “uni-directional” means that the device blocks voltage and conducts current in the same direction.

The first/second power semiconductor device may comprise one or more of a power MOSFET, an IGBT, a WBG power semiconductor device, and/or a power diode, etc.

At least one of the first and second power semiconductor devices may comprise a wide bandgap power semiconductor device.

The power semiconductor module may further comprise first, second and third power terminals electrically connected to the first, second and third conductive tracks, respectively.

The first and second power terminals may be DC input terminals, and the third power terminal may be an AC output terminal.

The first and second power terminals may be for connecting to a DC power supply which provides a higher voltage potential at the second power terminal than at the first power terminal.

The first, second and third power terminals may be directly mounted on the first, second and third conductive tracks, respectively.

In other words, the first, second and third power terminals may be arranged between the substrate and the circuit board.

With the expression “directly mounted”, it is meant that no other structure is between the power terminals and the conductive tracks (except a small amount of bonding material used). The first, second and third power terminals may be directly mounted on the conductive tracks by sintering, soldering or bonding by conductive epoxy resin.

Advantageously, directly mounting the power terminals on the conductive tracks improves cooling of the power terminals, which is critical for reliability of the module (e.g., joints to the power terminals and surrounding dielectric encapsulation). This is particularly important if the first/second power semiconductor device uses wide bandgap chips, since wide bandgap chips have higher current densities and higher heat flux densities than traditional silicon chips.

The power semiconductor module may comprise an encapsulant encapsulating the first and second power semiconductor devices and a space between the circuit board and the substrate. At least a part of each of the first, second and third power terminals may be exposed to an exterior of the power semiconductor module (by for example protruding beyond the encapsulant).

The first and second power electrodes may be both arranged on a surface of the first power semiconductor device that faces the circuit board.

Further or alternatively, the third and fourth power electrodes may be both arranged on a surface of the second power semiconductor device that faces the circuit board.

In other words, the first/second power semiconductor device may be lateral devices.

The use of lateral devices means that the power current loops of a circuit structure realised by the power semiconductor module are contained within the circuit board and the conductive regions (close to the top surface) of the lateral devices. As compared to the use of vertical devices (where power electrodes are arranged on opposite surfaces of the device), using lateral devices is beneficial for improving the effectiveness of magnetic flux cancellation because the distance between conductors of opposing current flow directions can be kept at a relatively short level and is not opened up by the thickness of the first/second power semiconductor device.

The first/second power semiconductor device may be mounted on the patterned electrically conductive layer of the substrate.

The plurality of electrically conductive layers may further comprise fourth and fifth electrically conductive layers which are spaced apart from one another along the stacking direction. The fourth electrically conductive layer may be electrically connected to a first through-layer via of the circuit board, which may be further electrically connected to the first electrically conductive layer. The fifth electrically conductive layer may be electrically connected to a second through-layer via of the circuit board, which may be further electrically connected to the second electrically conductive layer.

Advantageously, the power circuit current of the power semiconductor module is carried in more than one layer of the circuit board. This is useful for increasing conductor cross-sectional area and reducing the overall electrical resistance and inductance of the electrical interconnections between the first and second power semiconductor devices and the substrate.

The third electrically conductive layer may be arranged between the second and fifth electrically conductive layers, which may be further arranged between the first and fourth electrically conductive layers.

Advantageously, external environment (where other sensitive circuitry may be located) is shielded from electromagnetic emissions from the third electrically conductive layer.

The plurality of electrically conductive layers may further comprise a sixth electrically conductive layer which is electrically connected to a third through-layer via of the circuit board. The third through-layer via may be further electrically connected to the third electrically conductive layer.

The third and sixth electrically conductive layers may be arranged between the second and fifth electrically conductive layers.

The first power semiconductor device may comprise a control electrode configured to switch a power current flowing between the first power electrode and the second power electrode.

The patterned electrically conductive layer may comprise fourth and fifth conductive tracks which are spaced apart from one another. The power semiconductor module may comprise fourth and fifth control terminals electrically connected to the fourth and fifth conductive tracks, respectively.

The plurality of electrically conductive layers may further comprise seventh and eighth electrically conductive layers which are spaced apart from one another along the stacking direction. The control electrode may be electrically connected to the seventh electrically conductive layer which may be further electrically connected to the fourth conductive track. The first power electrode may be electrically connected to the eighth electrically conductive layer, which may be further electrically connected to the fifth conductive track.

The seventh and eighth electrically conductive layers may be separated by a single electrically conductive layer.

Advantageously, this arrangement allows the seventh and eighth electrically conductive layers to be closely coupled, thereby promoting flux cancellation and a reduction of parasitic inductances of electrical interconnections between the fourth/fifth control terminals and the control/first power electrode. The reduced parasitic inductances improve the switching speed of the first power semiconductor device, and also reduce the risks of falsely triggering the first power semiconductor device.

The plurality of electrically conductive layers may further comprise a seventh electrically conductive layer which is patterned to form two or more conductive tracks, the two or more conductive tracks being spaced apart from one another. The control electrode may be electrically connected to one conductive track of the seventh electrically conductive layer, the one conductive track being further electrically connected to the fourth conductive track. The first power electrode may be electrically connected to another conductive track of the seventh electrically conductive layer, the another conductive track being further electrically connected to the fifth conductive track.

The first and second electrically conductive layers may be arranged between the third electrically conductive layer and the seventh electrically conductive layer.

Advantageously, the control circuit of the first power semiconductor device, which is a sensitive element of the power semiconductor module, is shielded from EMI caused by high-speed electrical transients in the third electrically conductive layer.

The seventh electrically conductive layer may be arranged between the substrate and each of the first, second and third electrically conductive layers.

The seventh and eighth electrically conductive layers may be arranged between the substrate and each of the first, second and third electrically conductive layers.

The first and second electrically conductive layers may be arranged between the third electrically conductive layer and the seventh and eighth electrically conductive layers.

The above described optional features apply to the second power semiconductor device similarly.

The circuit board may be a flexible circuit board. Advantageously, a flexible circuit board is useful for accommodating differences in thickness of components and devices mounted on the substrate.

The plurality of electrically conductive layers may comprise copper. The plurality of electrically insulating layers may comprise polyimide. The plurality of electrically conductive layers and the plurality of electrically insulating layers may be arranged in an alternating manner.

The circuit board may have a total thickness of not greater than 1 millimetre.

The circuit board may also be referred to as a foil composite or a laminate structure.

The plurality of electrically conductive layers may further comprise a patterned interface layer on a surface of the circuit board that faces the first and second power semiconductor device.

The patterned interface layer may comprise spaced-apart conductive regions which are electrically connected to the first to third conductive tracks (and the first to fourth power electrodes), respectively.

The circuit board may further comprise at least one through-layer via which electrically connects each conductive region of the patterned interface layer to a respective one of the first to third electrically conductive layers.

The surface of the electrically insulating body may be a first surface and faces the first and second power semiconductor devices. The electrically insulating body may further comprise a second surface opposite to the first surface. The power semiconductor module further comprises a heat removal structure thermally coupled to the second surface of the electrically insulating body.

The substrate may comprise a further electrically conductive layer arranged on the second surface of the electrically insulating body.

Within the present disclosure, the term “thermally coupled” includes that one or more intervening element(s) may exist between the thermally coupled elements.

According to a second aspect of this disclosure there is provided a method of operating the power semiconductor module of the first aspect. The method comprises: electrically connecting the first and second conductive tracks to a DC power supply such that the second conductive track operates with a higher voltage potential than the first conductive track.

The first conductive track may be electrically connected to ground.

The first power semiconductor device may comprise a first control electrode configured to switch a power current flowing between the first power electrode and the second power electrode. The second power semiconductor device may comprise a second control electrode configured to switch a power current flowing between the first power electrode and the second power electrode. The method may further comprises: applying control signals to the first control electrode and the second control electrode so as to generate an AC output at the third conductive track.

According to a third aspect of this disclosure, there is provided a method of manufacturing a power semiconductor module, comprising: attaching first and second power semiconductor devices to a circuit board, wherein the circuit board comprises a plurality of electrically conductive layers stacked with a plurality of electrically insulating layers along a stacking direction, wherein at least one of the electrically insulating layers is arranged between adjacent ones of the electrically conductive layers, and the plurality of electrically conductive layers comprises first, second and third electrically conductive layers which are spaced apart from one another along the stacking direction, and the second electrically conductive layer is arranged between the first and third electrically conductive layers, and wherein the first power semiconductor device comprises first and second power electrodes, and the second power semiconductor device comprises third and fourth power electrodes; mounting the circuit board to a substrate such that the first and second power semiconductor devices are arranged between the circuit board and the substrate, wherein the substrate comprises an electrically insulating body and a patterned electrically conductive layer arranged on a surface of the electrically insulating body, and wherein the patterned electrically conductive layer comprises first, second and third conductive tracks which are spaced apart from one another; wherein attaching the first and second power semiconductor devices to the circuit board comprises: electrically connecting the first power electrode to the first electrically conductive layer; electrically connecting each of the second and third power electrodes to the third electrically conductive layer; and electrically connecting the fourth power electrode to the second electrically conductive layer; and wherein mounting the circuit board to the substrate comprises: electrically connecting the first electrically conductive layer to the first conductive track; electrically connecting the third electrically conductive layer to the third conductive track; and electrically connecting the second electrically conductive layer to the second conductive track.

The method may further comprise: mounting first, second and third power terminals directly on the first, second and third conductive tracks of the substrate, respectively.

The term “about” or “approximately” used in the present disclosure indicate a degree of variability (e.g., 20%) in the stated numerical values.

It would also be understood that the terms “first” to “eighth” are simply used in the present disclosure to label the relevant elements (e.g., “power electrode”, “electrically conductive layer” etc.) for the ease of description, and do not imply any limitations to the sequence, locations or total number of the relevant elements.

Where appropriate any of the optional features described above in relation to one of the aspects of the disclosure may be applied to another one of the aspects of the disclosure.

### BRIEF DESCRIPTION OF THE DRAWINGS

In order that the disclosure may be more fully understood, a number of embodiments of the disclosure will now be described, by way of example, with reference to the accompanying drawings, in which:

FIG. 1 schematically illustrates a circuit diagram of a half-bridge circuit structure with parasitic capacitances;

FIG. 2 is a schematic representation of a top plan view of a power semiconductor module according to a first embodiment of the present disclosure;

FIG. 3 a schematic representation of a cross-sectional view of the power semiconductor module of FIG. 2 when the module is cut along line III-III′ in FIG. 2;

FIG. 4 is a schematic representation of a top plan view of a substrate used within the power semiconductor module of FIG. 2 with power semiconductor devices mounted thereon;

FIG. 5 is a schematic representation of a bottom plan view of a circuit board used within the power semiconductor module of FIG. 2;

FIG. 6 schematically illustrates paths of power circuit currents through the power semiconductor module of FIG. 2;

FIG. 7 schematically illustrates paths of gate circuit currents for low-side devices of the power semiconductor module of FIG. 2;

FIG. 8 schematically illustrates paths of gate circuit currents for high-side devices of the power semiconductor module of FIG. 2;

FIG. 9 is a schematic representation of a top plan view of a power semiconductor module according to a second embodiment of the present disclosure;

FIG. 10 is a schematic representation of a top plan view of a power semiconductor module according to a third embodiment of the present disclosure;

FIG. 11 a schematic representation of a cross-sectional view of a power semiconductor module according to a fourth embodiment of the present disclosure;

FIG. 12 schematically illustrates processing steps of a method for manufacturing a power semiconductor module according to the present disclosure.

In the figures, like parts are denoted by like reference numerals.

It will be appreciated that the drawings are for illustration purposes only and are not drawn to scale.

### DETAILED DESCRIPTION OF THE PREFERRED EMBODIMENTS

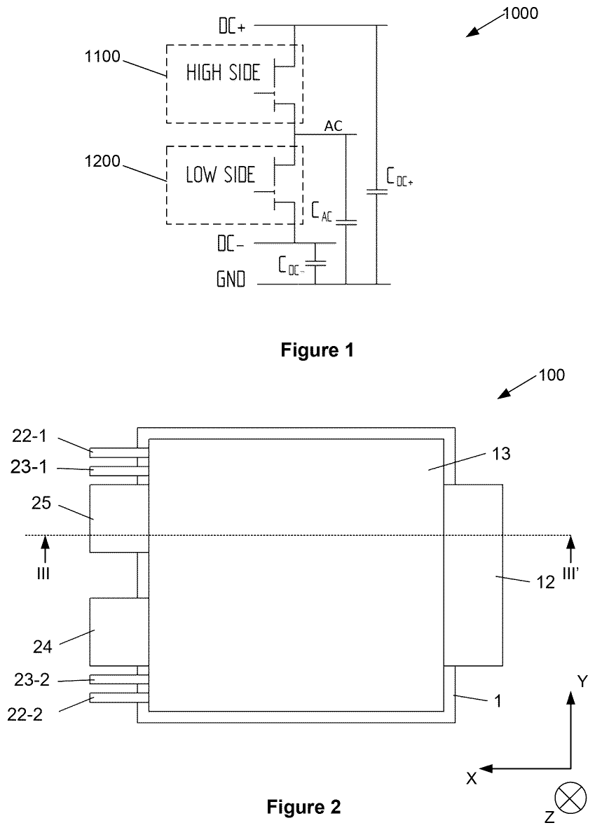

FIGS. 2 to 5 schematically illustrates the structure of a power semiconductor module 100 (hereinafter, “module 100”) that realises the half-bridge circuit 1000 of FIG. 1.

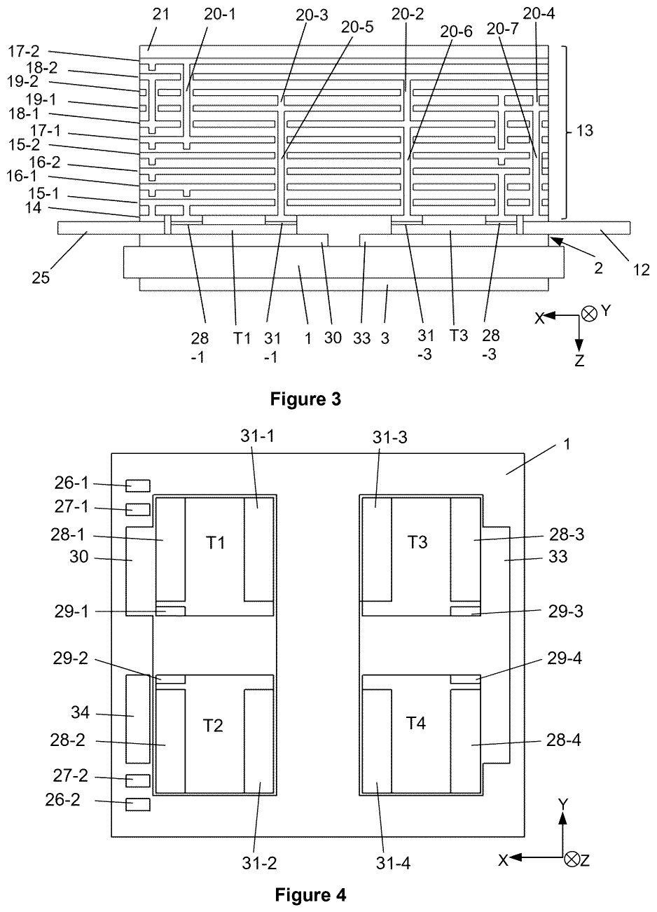

FIG. 2 is a top plan view of the module 100 shown in an X-Y plane when the module 100 is viewed along a vertical Z direction from the top. As shown in FIG. 2, the module 100 includes power terminals 25, 24, 12 which correspond to the DC− power terminal, the DC+ power terminal and the AC output terminal of the half-bridge circuit 1000, respectively. The module 100 further includes gate control terminals 22-1 and 22-2 (which are collectively referred to as 22), and Kelvin source control terminals 23-1 and 23-2 (which are collectively referred to as 23). The module 100 also has an electrically insulating body 1 and a circuit board 13 which are described in more detail below with reference to FIGS. 3 to 5.

FIG. 3 is a cross-sectional view of the module 100 along an X-Z plane when the module 100 is cut along a line III-III′ in FIG. 2. As shown in FIG. 3, the electrically insulating body 1 has a patterned electrically conductive layer 2 arranged on its top surface, and another electrically conductive layer 3 arranged on its opposite bottom surface. The electrically insulating body 1 and the conductive layers 2, 3 are collectively referred to as a substrate of the module 100. The electrically insulating body 1 is typically made of ceramic or a suitable polymer. The conductive layers 2, 3 may be made of copper or other suitable conducting material such aluminum, copper-molybdenum alloy, or copper-tungsten alloy etc. The substrate may be a direct bonded copper (DBC) substrate, a directed bonded aluminium (DBA) substrate or an active metal brazed (AMB) substrate.

FIG. 3 also shows that power semiconductor devices T1 and T3 are mounted on the patterned electrically conductive layer 2. A circuit board 13 is further mounted on top of the power semiconductor devices T1 and T3. Therefore, the circuit board 13, the power semiconductor devices T1 and T3, and the substrate are stacked along the vertical Z direction.

FIG. 4 shows a top plan view of the substrate with power semiconductor devices (hereinafter, “devices”) mounted thereon. The view of FIG. 4 is from the same angle as the view of FIG. 2. It would be understood that in FIG. 4, the “top surface” of an element refers to the visible surface of the relevant element, and the “bottom surface” is at an opposite side of the element and hence remains invisible.

As shown in FIG. 4, the patterned electrically conductive layer 2 includes a plurality of conductive tracks that are spaced apart from one another (hence electrically insulated from one another without further electrical connections). The plurality of conductive tracks include a first conductive track 30, a second conductive track 34, and a third conductive track 33, which are electrically connected to the power terminals 25, 24, 12, respectively. The plurality of conductive tracks further include substrate gate pads 26-1, 26-2 (collectively referred to as 26) which are electrically connected to the gate control terminals 22-1 and 22-2, respectively, as well as substrate Kelvin source pads 27-1, 27-2 (collectively referred to as 27) which are electrically connected to the Kelvin source control terminals 23-1 and 23-2, respectively. The gate pads 26 and the Kelvin source pads 27 may also be referred to as “fourth conductive track” and “fifth conductive track” of the patterned electrically conductive layer 2, respectively.

Two devices T1 and T2 are mounted on the first conductive track 30 and are laterally spaced from one another along the Y direction. The devices T1 and T2 are electrically connected in parallel with each other and collectively form the low-side power switch 1200. Similarly, two devices T3 and T4 are mounted on the third conductive track 33 and are laterally spaced from one another along the Y direction. The devices T3 and T4 are electrically connected in parallel and collectively form the high-side power switch 1100. The devices T1-T4 may be pre-packaged bare dies or packaged chips.

While it is not shown in any of the figures, it would be understood that bonding materials (e.g., solder or sintering paste, or conductive epoxy resin) may be used between the bottom surfaces of the devices T1 to T4 (or the bottom surfaces of the terminals 12 and 22-25) and the top surfaces of the conductive tracks 26, 27, 30, 33, 34, so as to securely bond the devices/terminals to the conductive tracks.

In this example, the devices T1 to T4 are GaN HEMTs. However, it would be appreciated that the devices T1 to T4 may be other types of WBG power transistors, or may be based upon non-WBG semiconductor materials (e.g., Silicon). For example, the devices T1 to T4 may comprise one or more of insulated gate bipolar transistors (IGBT), power metal-oxide-semiconductor field-effect transistors (MOSFET), injection enhanced gate transistors (IEGT), power bipolar junction transistors (BJT), integrated gate-commutated thyristors (IGCT), and gate turn-off thyristors (GTO), etc. In the event that the devices T1 to T4 are IGBT-based, the Kelvin source control terminals 23 may be referred to as auxiliary emitter terminals. Further, one or more of the devices T1 to T4 may further include a power diode (such as a fast recovery diode or a Schottky diode) in anti-parallel connections with the power transistor therein. Further still, it would be understood that the number of devices included within each of the high-side and low-side power switches 1100, 1200 can be suitably varied depending upon the required rating of the half-bridge circuit 1000.

With reference to FIG. 4, the device T1 has a gate electrode 29-1, a source electrode 28-1 and a drain electrode 31-1, all of which are formed at the top surface of the device T1. The gate electrode 29-1 is a control electrode, and the source and drain electrodes 28-1, 31-1 are power electrodes. In particular, a voltage difference between the gate electrode 29-1 and the source electrode 28-1 determines the on/off status of a power current path between the drain electrode 31-1 and the source electrode 28-1. Similarly, the device T2 has a gate electrode 29-2, a source electrode 28-2 and a drain electrode 31-2 at its top surface. The device T3 has a gate electrode 29-3, a source electrode 28-3 and a drain electrode 31-3 at its top surface. The device T4 has a gate electrode 29-4, a source electrode 28-4 and a drain electrode 31-4 at its top surface. The bottom surfaces of the devices T1-T4 are semiconductor substrates of the devices T1-T4 and are directly mounted on the conductive tracks 30, 33 as described above. Therefore, the devices T1-T4 are thermally coupled to the substrate. The source electrodes 28-1, 28-2 of the low-side devices T1, T2 may be referred to as “first power electrode”. The drain electrodes 31-1, 31-2 of the low-side devices T1, T2 may be referred to as “second power electrode”. The source electrodes 28-3, 28-4 of the high-side devices T3, T4 may be referred to as “third power electrode”. The drain electrodes 31-3, 31-4 of the high-side devices T3, T4 may be referred to as “fourth power electrode”. The devices T1-T4 are typically uni-directional devices, meaning that the devices block voltage and conduct current in the same direction. For example, the low-side devices T1, T2 block a voltage with a higher potential at the second/drain power electrode than at the first/source power electrode, and the high-side devices T3, T4 block a voltage with a higher potential at the fourth/drain power electrode than at the third/source power electrode.

The circuit board 13 is used to realise the electrical connections between the electrodes 28, 29, 31 of the devices T1-T4 and the conductive tracks 26, 27, 30, 33, 34 of the patterned electrically conductive layer 2 (hence the terminals 12, 22-25 of the module 100).

A cross-sectional view of the circuit board 13 is shown in FIG. 3. With reference to FIG. 3, the circuit board 13 includes a patterned electrically conductive interface layer 14 (hereinafter, “interface layer”) at its bottom surface for direct bonding with the electrodes 28, 29, 31 of the devices T1-T4 and the terminals 12, 22-25 of the module 100. The circuit board 13 further includes multiple electrically conductive layers 15-1, 16-1, 16-2, 15-2, 17-1, 18-1, 19-1, 19-2, 18-2 and 17-2 arranged on the interface layer 14 from bottom to top (i.e., along a Z− direction). The circuit board 13 also has electrically insulating layers (not labelled) stacked with the conductive layers in an alternating manner along a stacking direction (e.g., the Z or Z− direction). While FIG. 3 shows that a single electrically insulating layer is arranged between adjacent conductive layers, it would be appreciated that more than one electrically insulating layer may be used between some of the conductive layers. The conductive layers 17-1, 18-1, 19-1 may be referred to as “first electrically conductive layer” to “third electrically conductive layer”, respectively. The conductive layers 17-2, 18-2, 19-2 may be referred to as “fourth electrically conductive layer” to “sixth electrically conductive layer”, respectively. The conductive layers 16-1, 16-2 may be collectively referred to as “seventh conductive layer”, and the conductive layers 15-1, 15-2 may be collectively referred to as “eighth conductive layer”.

Due to the existence of the electrically insulating layers, adjacent conductive layers would not be electrically shorted to one another without the use of conductive through-layer vias. As shown in FIG. 3, the conductive layers 17-1 and 17-2 (collectively referred to as 17) are electrically connected to one another by a through-layer via 20-1. Therefore, the conductive layers 17 share a common voltage potential during operation of the module 100. Similarly, the conductive layers 18-1 and 18-2 (collectively referred to as 18) are electrically connected to one another by a through-layer via 20-2. Therefore, the conductive layers 18 share a common potential in use. The conductive layers 19-1 and 19-2 (collectively referred to as 19) are electrically connected to one another by through-layer vias 20-3, 20-4. Therefore, the conductive layers 19 share a common potential in use.

In FIG. 3, the through-layer vias 20 are shown in defined locations for ease of understanding. It would be understood that in reality, the through-layer vias 20 are distributed across the whole X-Y plane of the circuit board, so as to minimise the resistance and inductance between interconnected layers. The through-layer vias of the circuit board 13 generally extend along the vertical stacking direction (e.g., the Z or Z− direction), but it would be understood that the vias may alternatively form a small angle with respect to the stacking direction.

A top insulating layer 21 covers the top electrically conductive layer 17-2 to protect the conductive layers from external environment.

The multi-layer circuit board 13 may be manufactured by common processes. A flexible circuit board 13 is preferred to accommodate differences in thicknesses of the devices T1-T4 and the terminals 12, 22-25, such that the circuit board 13 can be easily bonded to both the electrodes at the top surfaces of the devices T1-T4 and the top surfaces of the terminals 12, 22-25. The electrically conductive layers 15-19 may be made of copper, and the electrically insulating layers in-between may be made of high temperature insulating material, such as polyimide. Typical layer thicknesses are 70 μm for each of the electrically conductive layers and 12um for each of the electrically insulating layers, although other thicknesses are possible. In general, thick conductor and thin insulator layers are preferred. This is described below in more detail. With the typical layer thicknesses described above, the total thickness of the circuit board 13 along the stacking direction is generally within about 1 millimeter (mm). In the meantime, the size of the circuit board 13 may be around 30-50 mm along the X axis, and 50-60 mm along the Y axis. Therefore, the thickness of the circuit board 13 is merely a small percentage (e.g., less than 5%) of its size along the X or Y axis. This allows the circuit board 13 to be easily deformable, thereby enhancing the flexibility of the circuit board 13. The circuit board 13 may also be referred to as a foil composite or a laminate structure.

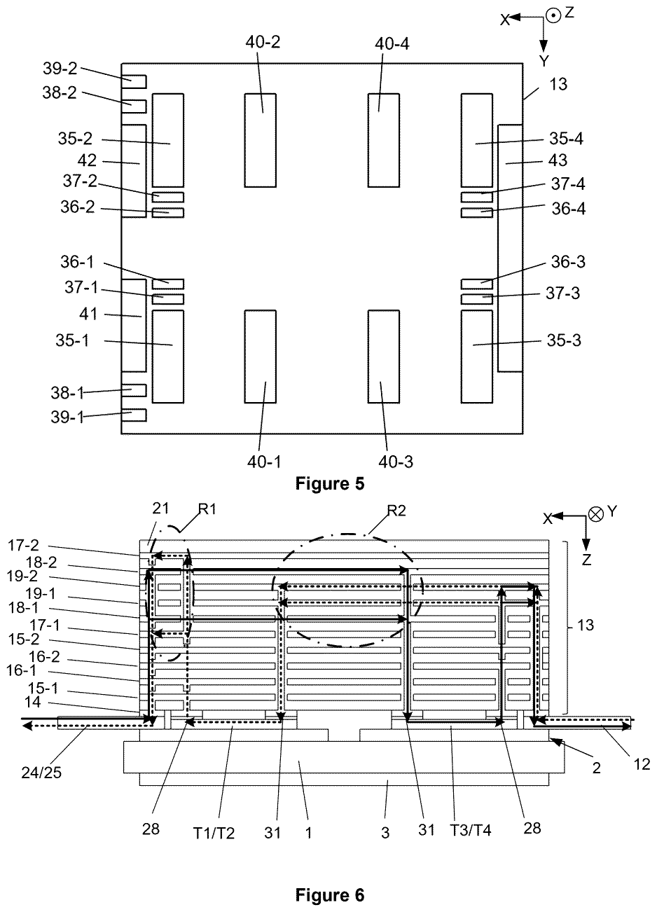

FIG. 5 is a bottom plan view of the circuit board 13 shown in the X-Y plane when the circuit board 13 is viewed along the Z− direction from the bottom. It would be understood that in FIG. 5, the “bottom surface” of an element refers to the visible surface of the relevant element, and the “top surface” is at an opposite side of the element and hence remains invisible. Because the interface layer 14 is at the bottom surface of the circuit board 13, FIG. 5 therefore shows the layout of the interface layer 14.

As shown in FIG. 5, the interface layer 14 is a patterned layer including a plurality of conductive regions that are spaced apart from one another (hence electrically insulated from one another without further electrical connections). The interface layer 14 may be formed by selectively etching a continuous electrically conductive layer. The plurality of conductive regions include source contact regions 35-1 to 35-4 for electrical connection with the source electrodes 28-1 to 28-4 of the devices T1-T4, respectively, drain contact regions 40-1 to 40-4 for electrical connection with the drain electrodes 31-1 to 31-4 of the devices T1-T4, gate contact regions 36-1 to 36-4 for electrical connection with the gate electrodes 29-1 to 29-4 of the devices T1-T4 and Kelvin source contact regions 37-1 to 37-4 for electrical connection with the source electrodes 28-1 to 28-4 of the devices T1-T4. The plurality of conductive regions further include power contact regions 41-43 for electrical connection with the DC− terminal 25, the DC+ terminal 24 and the AC terminal 12 of the module 100 (hence the conductive tracks 30, 34, 33 of the patterned electrically conductive layer 2 as shown in FIG. 4). The plurality of conductive regions further include control-signal contact regions 38-1, 39-1, 38-2, 39-2 for electrical connection with the control terminals 23-1, 22-1, 23-2, 22-2 of the module 100 respectively (hence the conductive tracks 27-1, 26-1, 27-2, 26-2 of the patterned electrically conductive layer 2 as shown in FIG. 4).

When the circuit board 13 is mounted on top of the devices T1-T4 and the substrate as shown in FIG. 3, the conductive regions of the interface layer 14 are directly mounted on the corresponding electrodes of the devices T1-T4 and the corresponding terminals of the module 100 as described above. Therefore, the conductive regions of the interface layer 14 may also be regarded as bonding pads.

The circuit board 13 further includes through-layer vias which electrically connect the conductive regions of the interface layer 14 to corresponding one(s) of the electrically conductive layers 15 to 19 within the circuit board 13.

In particular, the contact regions 40-3 and 40-4 are electrically connected to the conductive layers 18 by through-layer vias (e.g., 20-6 in FIG. 3). The conductive layers 18 are electrically connected to the power contact region 42 by further through-layer vias (not shown in FIG. 3). Therefore, the drain electrodes 31-3, 31-4 of the high-side devices T3, T4 are electrically connected to the conductive layers 18, which are electrically connected to the DC+ power terminal 24.

The contact regions 35-3, 35-4, 40-1, 40-2 are electrically connected to the conductive layers 19 by through-layer vias (e.g., 20-5 in FIG. 3). The conductive layers 19 are electrically connected to the power contact region 43 by further through-layer vias (e.g., 20-7 in FIG. 3). Therefore, the source electrodes 28-3, 28-4 of the high-side devices T3, T4 and the drain electrodes 31-1, 31-2 of the low-side devices T1, T2 are electrically connected to the conductive layers 19, which are electrically connected to the AC output power terminal 12.

The contact regions 35-1 and 35-2 are electrically connected to the conductive layers 17 by through-layer vias (not shown in FIG. 3). The conductive layers 17 are electrically connected to the power contact region 41 by further through-layer vias (not shown in FIG. 3). Therefore, the source electrodes 28-1, 28-2 of the low-side devices T1, T2 are electrically connected to the conductive layers 17, which are electrically connected to the DC− power terminal 25.

Therefore, the conductive layers 17, 18 and 19 may also be referred to DC−, DC+ and AC conductive layers, respectively, because they share the voltage potentials of the DC− power terminal 25, the DC+ power terminal 24, and the AC output power terminal 12.

Further, the gate contact regions 36-3, 36-4 are electrically connected to the conductive layer 16-2 by through-layer vias (not shown in FIG. 3). The conductive layer 16-2 is further electrically connected to the control-signal contact region 39-2 by further through-layer vias (not shown in FIG. 3). Therefore, the gate electrodes 29-3, 29-4 of the high-side devices T3 and T4 are electrically connected to the conductive layer 16-2, which is electrically connected to the gate control terminal 22-2. The Kelvin source contact regions 37-3, 37-4 are electrically connected to the conductive layer 15-2 by through-layer vias (not shown in FIG. 3). The conductive layer 15-2 is further electrically connected to the control-signal contact region 38-2 by further through-layer vias (not shown in FIG. 3). Therefore, the source electrodes 28-3, 28-4 of the high-side devices T3 and T4 are electrically connected to the conductive layer 15-2, which is electrically connected to the Kelvin source control terminal 23-2. Accordingly, the conductive layers 16-2, 15-2 of the circuit board 13 may also be referred to as Gate and Kelvin source control layers of the high-side devices T3, T4, because they share the voltage potentials of the control terminals 22-2, 23-2.

Similarly, the gate electrodes 29-1, 29-2 of the low-side devices T1 and T2 are electrically connected to the conductive layer 16-1, which is electrically connected to the gate control terminal 22-1, and the source electrodes 28-1, 28-2 of the low-side devices T1 and T2 are electrically connected to the conductive layer 15-1, which is electrically connected to the Kelvin source control terminal 23-1. Accordingly, the conductive layers 16-1, 15-1 of the circuit board 13 may also be referred to as Gate and Kelvin source control layers of the low-side devices T1, T2, because they share the voltage potentials of the control terminals 22-1, 23-1.

In use of the module 100, a DC power supply is connected between the DC+ power terminal 24 and the DC− power terminal 25, and control signals are applied to the gate control terminals 22 and the Kelvin source control terminals 23 to control the on/off statuses of the high-side devices T3, T4 and the low-side devices T1, T2, thereby controlling the voltage/current output by the AC power terminal 12. The module 100 typically provides one phase of a power converter at the AC power terminal 12. The use of the Kelvin source control terminals 23 reduces the power and control loop common inductance of the devices T1-T2, and of the devices T3-T4. Reducing the power and control loop common inductance is useful for improving the simultaneous switching of the devices T1-T2 (or the devices T3-T4), thereby improving the current sharing between the devices T1-T2 (or the devices T3-T4) and thus the reliability of the module 100 as a whole.

With reference to FIG. 3, the conductive layers of the circuit board 13 are arranged in such an order as to shield sensitive elements (e.g., the gate circuitry, and the DC− conductive layers 17) of the module 100 against EMI. The EMI is primarily caused by the current and voltage transients in the AC conductive layers 19. Therefore, the objective is to shield the sensitive elements from the AC conductive layers 19. In the example of FIG. 3, the pair of AC conductive layers 19 are first sandwiched between the pair of DC+ conductive layers 18. The pair of DC− conductive layers 17 then sandwich the DC+ conductive layers 18 and the AC conductive layers 19. Generally speaking, the voltage potential of the DC+ conductive layers 18 (which is equal to the potential of the DC+ power terminal 24) is nominally fixed by an external circuitry and is not a reference voltage for the gate circuitry of either high-side or low-side devices. Therefore, the DC+ conductive layers 18 shield the DC− conductive layers 17 from emissions of the AC conductive layers 19. The DC− conductive layers 17 are sensitive elements, because in some applications such as electric vehicles, noises on the DC− conductive layers 17 may affect other systems of the same vehicle via a shared ground terminal GND. The gate circuit layers 15, 16 are then positioned outside the DC−-DC+-AC−AC−DC+-DC− sandwich. In this way, the gate circuit layers 15, 16 are also shielded from EMI caused by the AC conductive layers 19.

Further, in the example of the module 100, since the AC conductive layers 19 are sandwiched by the DC+ conductive layers 18 and the DC− conductive layers 17, the environment outside the module 100 (where other sensitive circuitry may be located) is also shielded from EMI caused by the AC conductive layers 19.

FIG. 6 schematically illustrates power circuit current paths during operation of the module 100. In accordance with the electrical connections described above, it would be understood that power currents flow through multiple conductive layers of the circuit board 13 joined by vertical through-layer vias within the circuit board 13. Because the through-layer vias are not constrained within a single cross section (along the X-Z plane) of the module 100, the current paths are in fact three-dimensional. FIG. 6 is obtained by projecting the three-dimensional current paths of power circuit to a single two-dimensional X-Z plane. Therefore, overlapped vertical current paths as shown in FIG. 6 may not flow in the same physical conductors. However, overlapped horizontal current paths shown in FIG. 6 flow in the same conductive layer of the circuit board 13.

In FIG. 6, the solid lines show the power current flowing from the DC+ power terminal 24 to the AC output terminal 12. After entering the circuit board 13 (at the power contact region 42 of the interface layer 14), the power current flows upwards to the DC+ conductive layers 18, then laterally along the DC+ conductive layers 18, before flowing downwards to the drain electrodes 31 of the high-side devices T3, T4. The power current further flows laterally from the drain electrodes 31 to the source electrodes 28 of the high-side devices T3, T4, then upwards to the AC conductive layers 19, before following downwards to the AC output terminal 12.

The dashed lines in FIG. 6 shows the power current flowing from the AC output terminal 12 to the DC− power terminal 25. After entering the circuit board 13 (at the power contact region 43 of the interface layer 14), the power current flows upwards to the AC conductive layers 19, then laterally along the AC conductive layers 19, before flowing downwards to the drain electrodes 31 of the low-side devices T1, T2. The power current further flows laterally from the drain electrodes 31 to the source electrodes 28 of the low-side devices T1, T2, then upwards to the DC− conductive layers 17, before following downwards to the DC− power terminal 25.

As shown in FIG. 6, power circuit current paths are contained primarily within the electrically conductive layers of the circuit board 13. Considering that the total thickness of the circuit board 13 along the Z direction is within 1 mm, physical sizes of power current loops are significantly reduced as compared to the traditional module designs using wire bonds. Because current loops can cause radiated EMI, reducing the sizes of power current loops is useful for minimising EMI.

With reference to FIG. 6, it can be seen that the current path from DC+ to AC and the current path from AC to DC− are in close proximity. In particular, in regions R1 and R2, the two current paths have opposite flow directions, and the distance between the two current paths along the Z direction is merely the thickness of a single electrically insulating layer (in the order of tens of um). This arrangement promotes flux cancellation of the opposite current flows and accordingly causes a reduction of parasitic inductances in the interconnections between DC+/DC− and AC. In addition, the multi-layer nature of the circuit board 13 allows power circuit current to be carried in more than one conductive layer of the circuit board 13. In the example of the module 100, a pair of conductive layers (e.g., layers 17-1 & 17-2, 18-1 & 18-2 and 19-1 & 19-2) are always used to share the power circuit current at any point of the current paths. This arrangement effectively increases the cross-section area (along the Y-Z plane) of the power conductors, thereby reducing the overall electrical resistance and inductance in the interconnections between DC+/DC− and AC. Reducing the parasitic inductances in the interconnections between DC+/DC− and AC is useful for both minimising EMI and reducing the magnitude of voltage overshoot above the DC supply voltage of the module 100.

It would be understood that reducing the thickness of the electrically insulating layer between opposite current flows is useful for promoting flux cancellation of the opposite current flows, thereby causing a further reduction of parasitic inductances in the interconnections between DC+/DC− and AC. It would also be appreciated that increasing the thickness of electrically conductive layers is useful for reducing the overall electrical resistance and inductance in the interconnections between DC+/DC− and AC. Therefore, in general, thick electrically conductive layers and thin electrically insulating layers are preferred. A thickness of each electrically conductive layer may be in a range of between 50 μm and 140 μm, and a thickness of each electrically insulating layer may be in a range of between 10 μm and 30 μm, depending upon particular performance requirements.

Further with reference to FIGS. 2 and 4-6, it can be seen that the conduction path between DC+ and AC power terminals 24, 12, and the conduction path between DC− and AC power terminals 25, 12 are generally symmetric (e.g., on the X-Y plane) and have similar lengths within the circuit board 13 (e.g., on the X-Z plane). This means that the parasitic inductances in the interconnections between DC+/DC− and AC power terminals are generally balanced. This is also useful for reducing electromagnetic emissions of the module 100 because imbalanced inductances cause differential currents and thus EMI.

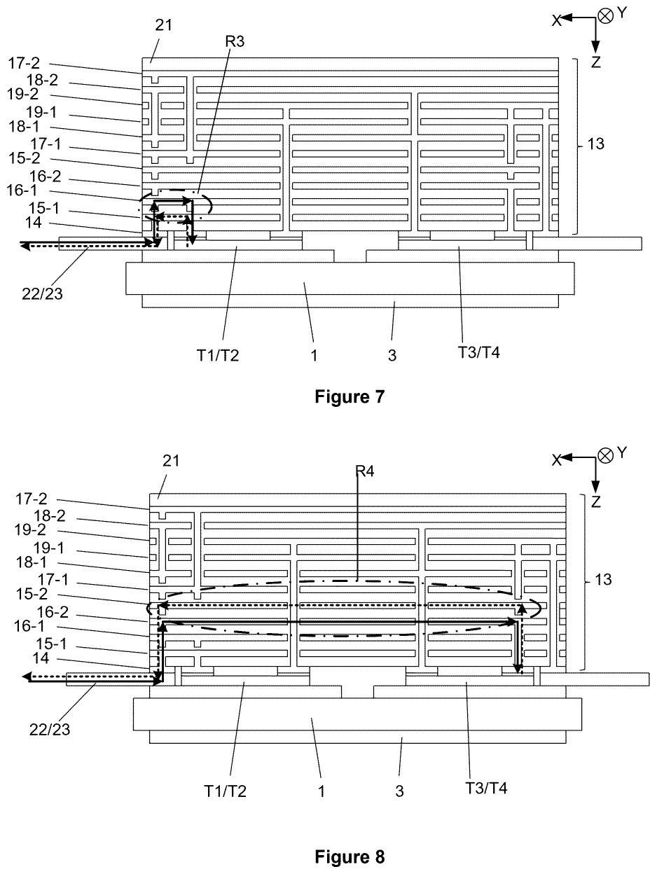

FIG. 7 schematically illustrates gate circuit current paths of the low-side devices T1, T2. FIG. 8 schematically illustrates gate circuit current paths of the high-side devices T3, T4. Similar to FIG. 6, FIGS. 7 and 8 are obtained by projecting real three-dimensional current paths to a single two-dimensional X-Z plane. Therefore, overlapped vertical current paths as shown in FIGS. 7 and 8 in fact may not flow in the same physical conductors. However, overlapped horizontal current paths shown in FIGS. 7 and 8 flow in the same conductive layer of the circuit board 13.

In each of FIGS. 7 and 8, the solid lines show the current flowing from the respective gate control terminal 22 of the module 100, via the corresponding gate control layer 16, to the gate electrodes 29 of the devices. The dashed lines in FIGS. 7 and 8 show the current flowing from the source electrodes 28 of the devices, via the corresponding Kelvin source control layer 15, to the respective Kelvin source control terminal 23 of the module 100.

With reference to FIGS. 7 and 8, it can be seen that, in regions R3 and R4, the gate circuit currents flow in opposite directions in the gate control layer 16 and the corresponding Kelvin source control layer 15, which are separated by a single electrical insulating layer. This arrangement allows the opposite current flows of the gate circuit to be closely coupled, thereby promoting flux cancellation and causing a reduction of parasitic inductances of electrical connections between the gate control terminal 22 and the gate electrode 29, and between the Kelvin source control terminal 23 and the source electrode 30. The reduced parasitic inductances improve the switching speed of the devices T1-T4, and also reduce the risks of falsely triggering the devices T1-T4.

The use of the multi-layer circuit board 13 further allows parasitic capacitances between DC+, DC− and AC potentials to be tailored by varying the area of mutual overlap. For example, in the circuit board 13, the DC+ conductive layers 18 and the DC− conductive layers 17 are separated by a single electrically insulating layer. This arrangement is useful for maximising the parasitic capacitance between the DC+ conductive layers 18 and the DC− conductive layers 17, and thus useful for reducing line voltage ripples caused by high-speed current transients produced by operation of the module 100.

In the example of the module 100, the DC+ and DC− power terminals 24, 25 and the AC power terminal 12 are mounted directly on the patterned electrically conductive layer 2 of the substrate. This direct mounting arrangement improves cooling of the power terminals, because heat generated on the power terminals can efficiently dissipate to exterior through the substrate and a heat sink attached to the bottom electrically conductive layer 3 of the substrate. Therefore, during operation of the module 100, joints between the power terminals and its surroundings (e.g., the substrate or dielectric encapsulation of the module 100) would not experience a significant temperature rise. Accordingly, reliability of the joints is improved, and the power cycling capability and the thermal reliability of the module 100 are also improved. The direct mounting arrangement of the power terminals is particularly meaningful for modules using WBG power semiconductor devices, since those devices have higher current densities and therefore higher heat flux densities than traditional silicon chips.

In addition, directly mounting the power terminals on the substrate necessitates the provision of conductive tracks 30, 33, 34 (which act as bonding pads) on the substrate. As described above, the conductive tracks 30, 34 are at DC− and DC+ potentials. The pad areas of the conductive tracks 30, 34 along the X-Y plane can be easily tailored in order to balance parasitic capacitances from DC+ to GND and DC− to GND. Balanced capacitances from DC+/DC− to ground minimise differential currents which are a cause of EMI. The parasitic capacitances may be balanced by making the conductive tracks 30, 34 occupy approximately the same area on the electrically insulating body 1. For example, the conductive track 34 may be modified to have a loop shape surrounding the conductive track 30.

As described above, traditional power semiconductor modules use a combination of wire bonds and patterned copper tracks on an electrically insulating body to realise electrical connections between power semiconductor chips and power terminals. The traditional power semiconductor modules therefore have planar circuit layouts, which have large footprints and high, typically unbalanced parasitics, and significantly limit product performance. In contrast, the module 100 of the present disclosure (in particular the use of the circuit board 13) provides improved design flexibility for more compact module footprints and optimised parasitics, which allows full exploitation of fast-switching capabilities of WBG power semiconductor devices (e.g., GaN HEMTs) within the module.

Within the module 100, each of the devices T1-T4 is a lateral power device, meaning that its power electrodes are formed on the same side (e.g., the top surface) of the device and that a power current flows laterally between the power electrodes as shown in FIGS. 3, 4 and 6. The use of lateral devices is particularly advantageous because, with reference to FIG. 6, the power current loops are contained within the circuit board 13 and the conductive regions (close to the top surface) of the lateral devices T1-T4. As compared to the use of vertical devices (where power electrodes are arranged on opposite surfaces of the device), using lateral devices is beneficial for improving the effectiveness of magnetic flux cancellation because the distance between conductors of opposing current flow directions can be kept at a relatively short level and is not opened up by the thickness of the vertical devices. However, it would be appreciated that the module 100 may be modified to use vertical power devices, while still achieving most of the improvements as described above over conventional power modules.

While it is not shown in any of FIGS. 2 to 8, it would further be understood that the module 100 typically includes an encapsulant which fills the space between the circuit board 100 and the substrate and seals the devices T1-T4. The encapsulant is useful for protecting the devices T1-T4 and its associated joints from humidity and corrosive gases. The encapsulant may be made of epoxy moulding compound (EMC), and may be applied by a transfer moulding process. Outer ends of the power terminals 12, 24-25 and the control terminals 22-23 of the module 100 would protrude over the encapsulant and be exposed to an exterior of the module 100. In addition, the bottom electrically conductive layer 3 of the substrate would be substantially exposed to the exterior of the module 100. In use, a heat removal structure (e.g., a heat sink) may be bonded to the bottom surface of the electrically conductive layer 3 via a thermal interface material (e.g., aluminium nitride), so as to dissipate heat generated by the devices T1-T4. Alternatively, the bottom electrically conductive layer 3 of the substrate may be omitted such that the heat removal structure is directly mounted to the bottom surface of the electrically insulating body 1.

It would further be appreciated that the module 100 may comprise different types/numbers of power semiconductor devices that are suitably interconnected to form a different circuit structure (e.g., multiple half-bridge structures, at least one phase of a three-level neutral point clamped inverter, etc.). In particular, this may be achieved by suitably modifying the number of conductive layers included within the circuit board 13, and/or the through-layer connections within the circuit board 13.

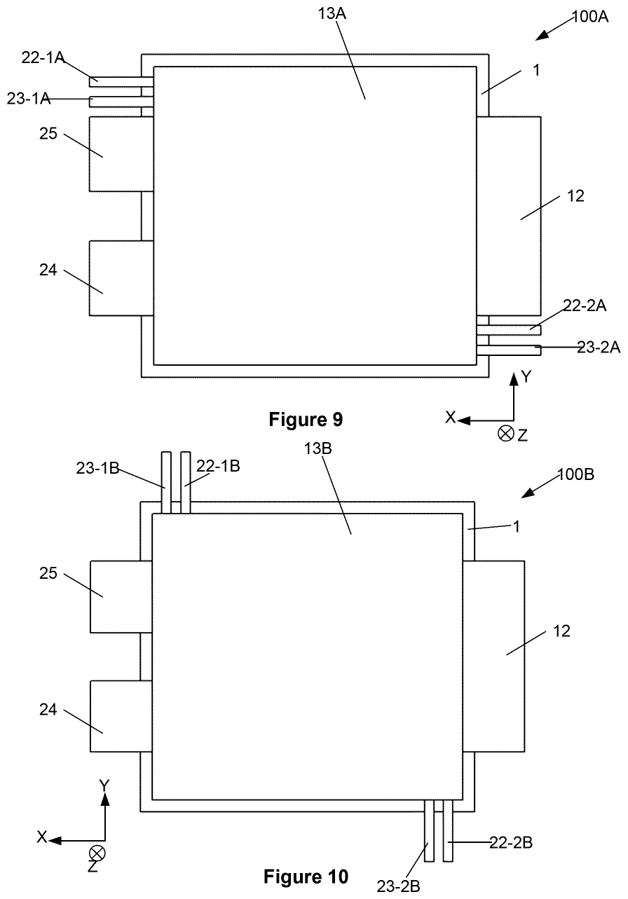

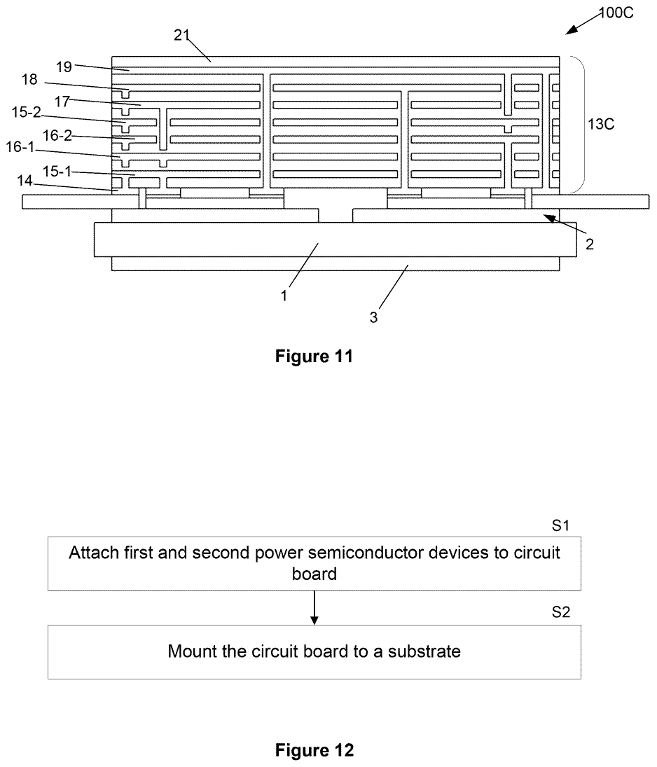

FIGS. 9 to 11 schematically illustrate power semiconductor modules 100A-100C according to second to fourth embodiments of the present disclosure. Elements of the modules 100A-100C that are identical to those of the module 100 are identified using the same labels. Elements of the modules 100A-100C that correspond to, but are different from those of the module 100 are labelled using the same numerals but with a letter ‘A’, ‘B’ or ‘C’ for differentiation. The features and advantages described above with reference to the first embodiment are generally applicable to the second to fourth embodiments.

The modules 100A and 100B differ from the module 100 in the positions of the control terminals 22A, 23A, 22B, 23B. This may be achieved by suitably modifying the positions of the conductive tracks 26, 27 in the patterned electrically conductive layer 2 of the substrate, the positions of the conductive regions 38, 39 in the patterned interface layer 14 of the circuit board 13, as well as the positions of the through-layer vias within the circuit board 13.

The module 100C differs from the module 100 in that the conductive layers 19-2, 18-2 and 17-2 are omitted such that the circuit board 13C includes a single DC− conductive layer 17, a single DC+ conductive layer 18 and a single AC conductive layer 19. In this way, shielding of the gate circuit layers 15, 16 from EMI caused by the AC conductive layer 19 is still provided by the DC+ and DC− conductive layers 17, 18, and shielding of the DC− conductive layer 17 from the EMI is still provided by the DC+ conductive layer 18. However, external environment is no longer shielded from the EMI caused by the AC conductive layer 19.

In the module 100C, the AC conductive layer 19 is further away from the substrate than either of the DC+ and DC− conductive layers 17, 18. In this way, the parasitic capacitance CAC between the AC conductive layer 19 and GND is minimised. This is useful for improving the switching performance of the module 100C.

It would be appreciated that conductive layers may be omitted from or added to the circuit board 15 in any suitable manner depending upon performance requirements of the module. For example, the AC conductive layers 22-1, 22-2 may be replaced by a single, thicker, conductive layer, and/or more than two interconnected conductive layers may be provided for each of the AC/DC+/DC− conductive layers. Further, the number of conductive layers in the circuit board 13 may be reduced by patterning at least one conductive layer (rather than using a plane-like layer that covers the entire footprint of the circuit board 13). For example, the gate control layer 16-1 and the Kelvin source control layer 15-1 may be replaced by a single patterned conductive layer having two or more conductive tracks which are spaced apart (hence electrically insulated) from one another, with one of the conductive tracks electrically connects the gate electrodes 29-1, 29-2 of the low-side devices to the control terminal 22-1 while another one of the conductive tracks electrically connects the source electrodes 28-1, 28-2 of the low-side devices to the control terminal 23-1. Similarly, the gate control layer 16-2 and the Kelvin source control layer 15-2 may be replaced by a single patterned conductive layer. Alternatively, the two gate control layers 16-1, 16-2 may be replaced by a single patterned conductive layer having two or more spaced-part conductive tracks, and/or the two Kelvin source control layers 15-1, 15-2 may be replaced by a single patterned conductive layer. In another example, all of the gate and Kelvin source control layers 15, 16 may be replaced by a single patterned conductive layer, if the layout of the layer permits such an arrangement.

It would also be appreciated that the layout of the patterned electrically conductive layer 2, the layout of the interface layer 14, and the layout of the devices T1-T4 may be suitably varied to differ from FIGS. 4 and 5.

FIG. 12 schematically illustrates processing steps of a method for manufacturing a power semiconductor module (e.g., either of the modules 100, 100A-100C).

At step S1, first and second power semiconductor devices (e.g., the low-side devices T1-T2, and the high-side device T3-T4) are attached to a circuit board (e.g., the circuit board 13). The circuit board comprises a plurality of electrically conductive layers stacked with a plurality of electrically insulating layers along a stacking direction (e.g., the direction Z), with at least one of the electrically insulating layers between adjacent ones of the electrically conductive layers. The plurality of electrically conductive layers comprises first, second and third electrically conductive layers (e.g., the layers 17-1, 18-1, 19-1) which are spaced apart from one another along the stacking direction. The second electrically conductive layer (e.g., the layer 18-1) is arranged between the first and third electrically conductive layers (e.g., the layers 17-1, 19-1). The first power semiconductor device (e.g., the low-side devices T1-T2) comprises first and second power electrodes (e.g., source electrodes 28-1, 28-2, and drain electrodes 31-1, 31-2). The second power semiconductor device (e.g., the high-side device T3-T4) comprises third and fourth power electrodes (e.g., source electrodes 28-3, 28-4, and drain electrodes 31-3, 31-4).

The first and second power semiconductor devices may be attached to the circuit board (in particular, a patterned electrically conductive interface layer, e.g., the layer 14, of the circuit board) by a flip-chip process.

Attaching first and second power semiconductor devices to the circuit board achieves simultaneously (i) an electrical connection between the first power electrode (e.g., the source electrodes 28-1, 28-2) to the first electrically conductive layer (e.g., the layer 17-1); (ii) an electrical connection between each of the second and third power electrodes (e.g., drain electrodes 31-1, 31-2 and source electrodes 28-3, 28-4) to the third electrically conductive layer (e.g., the layer 19-1); and (iii) an electrical connection between the fourth power electrode (e.g., the drain electrodes 31-3, 31-4) to the second electrically conductive layer (e.g., the layer 18-1).

At step S2, the circuit board is mounted to a substrate such that the first and second power semiconductor devices are arranged between the circuit board and the substrate. The substrate comprises an electrically insulating body (e.g., the body 1) and a patterned electrically conductive layer (e.g., the layer 2) arranged on a surface of the electrically insulating body. The patterned electrically conductive layer comprises first, second and third conductive tracks (e.g., tracks 30, 34, 33) which are spaced apart from one another.

Mounting the circuit board to the substrate achieves simultaneously (i) an electrical connection between the first electrically conductive layer to the first conductive track (e.g., the track 30); (ii) an electrical connection between the third electrically conductive layer to the third conductive track (e.g., the track 33); and (iii) an electrical connection between the second electrically conductive layer to the second conductive track (e.g., the track 34).

Between steps S1 and S2, there may be an optional step of mounting first, second and third power terminals (e.g., the DC− power terminal 25, the DC+ power terminal 24 and the AC output terminal 12) directly on the first, second and third conductive tracks of the substrate, respectively.

All joints are made by a suitable technology, which may include sintering, soldering or bonding by conductive epoxy resin.

The method may further include an optional processing step of encapsulating the first and second power semiconductor devices and a space between the circuit board and the substrate.

The terms “having”, “containing”, “including”, “comprising” and the like are open and the terms indicate the presence of stated structures, elements or features but not preclude the presence of additional elements or features. The articles “a”, “an” and “the” are intended to include the plural as well as the singular, unless the context clearly indicates otherwise.

The skilled person will understand that in the preceding description and appended claims, positional terms such as ‘top’, ‘bottom’, ‘lateral’, ‘vertical’, etc. are made with reference to conceptual illustrations of a semiconductor device, such as those showing standard cross-sectional perspectives and those shown in the appended drawings. These terms are used for ease of reference but are not intended to be of limiting nature. These terms are therefore to be understood as referring to a device when in an orientation as shown in the accompanying drawings.

Although the disclosure has been described in terms of preferred embodiments as set forth above, it should be understood that these embodiments are illustrative only and that the claims are not limited to those embodiments. Those skilled in the art will be able to make modifications and alternatives in view of the disclosure which are contemplated as falling within the scope of the appended claims. Each feature disclosed or illustrated in the present specification may be incorporated in the disclosure, whether alone or in any appropriate combination with any other feature disclosed or illustrated herein. This listing of claims will replace all prior versions and listings of claims in the application:

1. A power semiconductor module comprising:
a substrate comprising an electrically insulating body and a patterned electrically conductive layer arranged on a surface of the electrically insulating body, wherein the patterned electrically conductive layer comprises first, second and third conductive tracks which are spaced apart from one another;
a first power semiconductor device comprising first and second power electrodes;
a second power semiconductor device comprising third and fourth power electrodes; and
a circuit board, wherein: the first and second power semiconductor devices are arranged between the circuit board and the substrate; the circuit board comprises a plurality of electrically conductive layers stacked with a plurality of electrically insulating layers along a stacking direction; at least one of the electrically insulating layers is arranged between adjacent ones of the electrically conductive layers; and the plurality of electrically conductive layers comprises first, second and third electrically conductive layers which are spaced apart from one another along the stacking direction;
wherein:
the first power electrode is electrically connected to the first electrically conductive layer, and the first electrically conductive layer is further electrically connected to the first conductive track;
the second and third power electrodes are both electrically connected to the third electrically conductive layer, and the third electrically conductive layer is further electrically connected to the third conductive track;
the fourth power electrode is electrically connected to the second electrically conductive layer, and the second electrically conductive layer is further electrically connected to the second conductive track; and
the second electrically conductive layer is arranged between the first and third electrically conductive layers.

2. The power semiconductor module of claim 1, wherein the third electrically conductive layer is further away from the substrate than the first electrically conductive layer along the stacking direction.

3. The power semiconductor module of claim 1, wherein the first and second electrically conductive layers are separated by a single electrically insulating layer.

4. The power semiconductor module of claim 1, wherein the first and second conductive tracks occupy approximately the same area on the electrically insulating body.

5. The power semiconductor module of claim 1, wherein at least one of the first and second power semiconductor devices comprises a wide bandgap power semiconductor device.

6. The power semiconductor module of claim 1, further comprising first, second and third power terminals electrically connected to the first, second and third conductive tracks, respectively.

7. The power semiconductor module of claim 6, wherein the first and second power terminals are DC input terminals, and the third power terminal is an AC output terminal.

8. (canceled)

9. (canceled)

10. The power semiconductor module of claim 1, wherein the first and second power electrodes are both arranged on a surface of the first power semiconductor device that faces the circuit board.

11. The power semiconductor module of claim 1, wherein:
the plurality of electrically conductive layers further comprises fourth and fifth electrically conductive layers which are spaced apart from one another along the stacking direction, wherein:
the fourth electrically conductive layer is electrically connected to a first through-layer via of the circuit board, which is further electrically connected to the first electrically conductive layer; and
the fifth electrically conductive layer is electrically connected to a second through-layer via of the circuit board, which is further electrically connected to the second electrically conductive layer.

12. The power semiconductor module of claim 11, wherein the third electrically conductive layer is arranged between the second and fifth electrically conductive layers, which are further arranged between the first and fourth electrically conductive layers.

13. The power semiconductor module of claim 11, wherein the plurality of electrically conductive layers further comprises a sixth electrically conductive layer which is electrically connected to a third through-layer via of the circuit board, and the third through-layer via is further electrically connected to the third electrically conductive layer.

14. (canceled)

15. The power semiconductor module of claim 1, wherein the patterned electrically conductive layer comprises fourth and fifth conductive tracks which are spaced apart from one another, and the power semiconductor module comprises fourth and fifth control terminals electrically connected to the fourth and fifth conductive tracks, respectively.

16. The power semiconductor module of claim 15, wherein:
the first power semiconductor device comprises a control electrode configured to switch a power current flowing between the first power electrode and the second power electrode;
the plurality of electrically conductive layers further comprises seventh and eighth electrically conductive layers which are spaced apart from one another along the stacking direction;
the control electrode is electrically connected to the seventh electrically conductive layer which is further electrically connected to the fourth conductive track; and
the first power electrode is electrically connected to the eighth electrically conductive layer, which is further electrically connected to the fifth conductive track.

17. The power semiconductor module of claim 16, wherein the seventh and eighth electrically conductive layers are separated by a single electrically conductive layer.

18. The power semiconductor module of claim 15, wherein:
the first power semiconductor device comprises a control electrode configured to switch a power current flowing between the first power electrode and the second power electrode;
the plurality of electrically conductive layers further comprises a seventh electrically conductive layer which is patterned to form two or more conductive tracks, the two or more conductive tracks being spaced apart from one another;
the control electrode is electrically connected to one conductive track of the seventh electrically conductive layer, the one conductive track being further electrically connected to the fourth conductive track; and
the first power electrode is electrically connected to another conductive track of the seventh electrically conductive layer, the another conductive track being further electrically connected to the fifth conductive track.

19. The power semiconductor module of claim 16, wherein the first and second electrically conductive layers are arranged between the third electrically conductive layer and the seventh electrically conductive layer.

20. (canceled)

21. The power semiconductor module of claim 1, wherein the plurality of electrically conductive layers further comprise a patterned interface layer on a surface of the circuit board that faces the first and second power semiconductor device.

22. The power semiconductor module of claim 1, wherein:
the surface of the electrically insulating body is a first surface and faces the first and second power semiconductor devices, and the electrically insulating body further comprises a second surface opposite to the first surface; and
the power semiconductor module further comprises a heat removal structure thermally coupled to the second surface of the electrically insulating body.

23. A method of operating the power semiconductor module of claim 1, comprising:
electrically connecting the first and second conductive tracks to a DC power supply such that the second conductive track operates with a higher voltage potential than the first conductive track.

24. (canceled)

25. A method of manufacturing a power semiconductor module, comprising:
attaching first and second power semiconductor devices to a circuit board, wherein the circuit board comprises a plurality of electrically conductive layers stacked with a plurality of electrically insulating layers along a stacking direction, wherein at least one of the electrically insulating layers is arranged between adjacent ones of the electrically conductive layers, and the plurality of electrically conductive layers comprises first, second and third electrically conductive layers which are spaced apart from one another along the stacking direction, and the second electrically conductive layer is arranged between the first and third electrically conductive layers, and wherein the first power semiconductor device comprises first and second power electrodes, and the second power semiconductor device comprises third and fourth power electrodes; and
mounting the circuit board to a substrate such that the first and second power semiconductor devices are arranged between the circuit board and the substrate, wherein the substrate comprises an electrically insulating body and a patterned electrically conductive layer arranged on a surface of the electrically insulating body, and wherein the patterned electrically conductive layer comprises first, second and third conductive tracks which are spaced apart from one another;
wherein attaching the first and second power semiconductor devices to the circuit board comprises: electrically connecting the first power electrode to the first electrically conductive layer; electrically connecting each of the second and third power electrodes to the third electrically conductive layer; and electrically connecting the fourth power electrode to the second electrically conductive layer; and
wherein mounting the circuit board to the substrate comprises: electrically connecting the first electrically conductive layer to the first conductive track; electrically connecting the third electrically conductive layer to the third conductive track; and electrically connecting the second electrically conductive layer to the second conductive track.

26. (canceled)
